(19) United States
(12) Patent Application Publication
(10) Pub. No.: US 2010/0054044 A1
(43) Pub. Date: Mar. 4, 2010

(54) METHOD OF OPERATING NONVOLATILE MEMORY DEVICE

(76) Inventor: Ji Hyun SEO, Gyeonggi-do (KR)

Correspondence Address: IP & T Law Firm PLC, 7700 Little River Turnpike, Suite 207, Annandale, VA, 22003, US

(21) Appl. No.: 12/553,440

(22) Filed: Sep. 3, 2009

(30) Foreign Application Priority Data
Sep. 3, 2008 (KR) 10-2008-0086833

(51) Int. Cl. G11C 16/04; G11C 16/06

(52) U.S. Cl. 365/185.33; 365/185.18; 365/185.22

(57) ABSTRACT

A method of operating a nonvolatile memory device includes setting an initial cell current level, performing program and erase operations for each word line of a memory block, storing the cycling number of the program and erase operations, comparing the cycling number with a critical cycling number of the program and erase operations, lowering the initial cell current level when the cycling number are larger than the critical cycling number, and changing a program operation option based on the lowered initial cell current level

### CROSS-REFERENCE TO RELATED APPLICATION

Priority to Korean patent application number 10-2008-0086833 filed on Sep. 3, 2008, the entire disclosure of which is incorporated by reference herein, is claimed.

### BACKGROUND

An embodiment relates to an operation of a nonvolatile memory device and, more particularly, to a method of operating a nonvolatile memory device according to a change in the cell current level with the repetition of erase and deletion operations for a memory cell.

There is an increasing demand for semiconductor memory devices which can be electrically programmed and erased and can retain its data even though the supply of power is stopped. In order to develop high-capacity memory devices capable of storing lots of data, technologies for high-integration memory cells are being developed. To this end, a NAND type flash memory device in which a plurality of memory cells are coupled in series to thereby form one string and a plurality of the strings constitute one memory cell array was proposed.

Each of the flash memory cells of the NAND type flash memory device includes a current path which is formed between the source and the drain over a semiconductor substrate and a floating gate and a control gate which are formed between insulating layers over the semiconductor substrate. Furthermore, a program operation of the flash memory cell is for the most part performed by grounding the source and drain regions of the memory cell and the semiconductor substrate (i.e., a bulk region) and applying a high positive voltage to the control gate, thereby generating Fowler-Nordheim (F-N) tunneling between the floating gate and the semiconductor substrate. In such F-N tunneling, an electric field of the high voltage applied to the control gate causes the electrons of the bulk region to be accumulated in the floating gate, and so the threshold voltage of the memory cell rises.

Recently, in order to further increase the degree of integration of the flash memory cells, active research is being done on a multi-bit cell which is able to store plural data in a single memory cell. This type of a memory cell is commonly called a multi-level cell (MLC). A memory cell capable of storing a single bit is called a single level cell (SLC).

FIG. 1A is a cross-sectional view showing a state in which electrons have shifted according a program operation for a memory cell.

Referring to FIG. 1A, the memory cell of the flash memory device includes a substrate 110, a floating gate 120, and a control gate 130. A word line WL is coupled to the control gate 130. FIG. 1A is a simplified diagram showing the structure of the memory cell.

In order to store data in the memory cell, 0 V is applied to a bulk region and high voltage is applied to the word line WL, thereby making electrons shift to the floating gate 120. A state in which electrons exist in the floating gate 120 is called a program state, and, in the program state, the threshold voltage level of the memory cell rises.

The memory cell programmed as described above is erased as follows.

FIG. 1B is a cross-sectional view showing a state in which electrons have shifted according an erase operation for the memory cell.

Referring to FIG. 1B, in a program state in which electrons have shifted to the floating gate 120 of the memory cell, 0 V is applied to the word line and high voltage is applied to the bulk region. Thus, the electrons existing in the floating gate 120 shift to the substrate 110. A state in which electrons is removed from the floating gate 120 is called an erase state, and, in the erase state, the threshold voltage level of the memory cell decreases.

When the program and erase cycle is repeated as described above, some of the electrons that have shifted to the floating gate 120 may not shift to the substrate upon erase operation, and so they may be trapped in the floating gate 120.

FIG. 1C is a cross-sectional view showing a state in which electrons have shifted according to a program cycle and erase cycle of the memory cell.

Referring to FIG. 1C, as the program and erase cycle is repeated several hundreds of times or several hundreds of thousands of times, the number of electrons trapped in the floating gate 120 increases. With the increasing number of electrons trapped in the floating gate 120, the threshold voltage of the memory cell rises. In such a case, in response the same electric voltage is applied to the gate of the memory cell, a reference cell current (hereinafter referred to as an ‘I-trip’) is lowered.

### BRIEF SUMMARY

One or more embodiments relate to a method of operating a nonvolatile memory device which is set and configured to operate by changing an I-trip level with the repetition of an erase and program cycle.

According to an aspect of this disclosure, there is provided a method of operating a nonvolatile memory device, comprising setting an initial cell current level, cycling program and erase operations for each word line of a memory block, storing the cycling number of the program and erase operations, comparing the cycling number with a critical cycling number of the program and erase operations, lowering the initial cell current level when the cycling number are larger than the critical cycling number, and changing a program operation option based on the lowered initial cell current level.

According to another aspect of this disclosure, there is provided a method of operating a nonvolatile memory device, comprising setting an initial cell current level, cycling program and erase operations for each of memory block, storing the cycling number of the program and erase operations, comparing the cycling number with a critical cycling number of the program and erase operations, lowering the initial cell current level when the cycling number are larger than the critical cycling number, and changing a program operation option based on the lowered initial cell current level

The cycling number is stored in a flag cell coupled to each word line.

The cycling number is stored in separate storage means.

The cycling number is stored in a storage unit in a control unit for controlling the program operation.

The program operation option comprises a program verification voltage level or a number of a pulse in a program operation.

The program verification voltage level is lowered when lowering the initial cell current level.

### BRIEF DESCRIPTION OF THE DRAWINGS

FIG. 1A is a cross-sectional view showing a state in which electrons have shifted according a program operation for a memory cell;

FIG. 1B is a cross-sectional view showing a state in which electrons have shifted according an erase operation for a memory cell;

FIG. 1C is a cross-sectional view showing a state in which electrons have shifted according to a program cycle and erase cycle for a memory cell;

FIG. 2 is a block diagram of a nonvolatile memory device according to an embodiment;

FIG. 3A is a diagram showing an I-trip which is changed according to an erase/program cycle (hereinafter referred to as an ‘E/W cycle’);

FIG. 3B is a diagram showing a change in the program threshold voltage according to an E/W cycle;

FIG. 3C is a diagram showing the level of a change in the threshold voltage according to an E/W cycle and I-trip; and

FIG. 4 is a flowchart illustrating the operation of a nonvolatile memory device according to an embodiment.

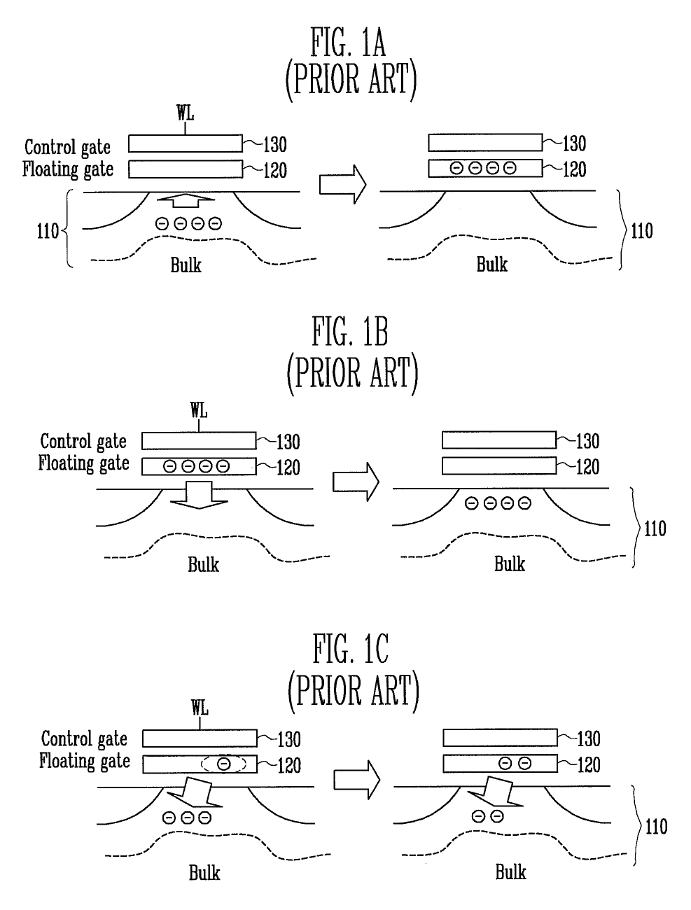

### DESCRIPTION OF EMBODIMENTS

Hereinafter, the present disclosure will be described in detail in connection with an embodiment with reference to the accompanying drawings. The drawing figures are provided to allow those having ordinary skill in the art to understand the scope of the embodiment of the disclosure.

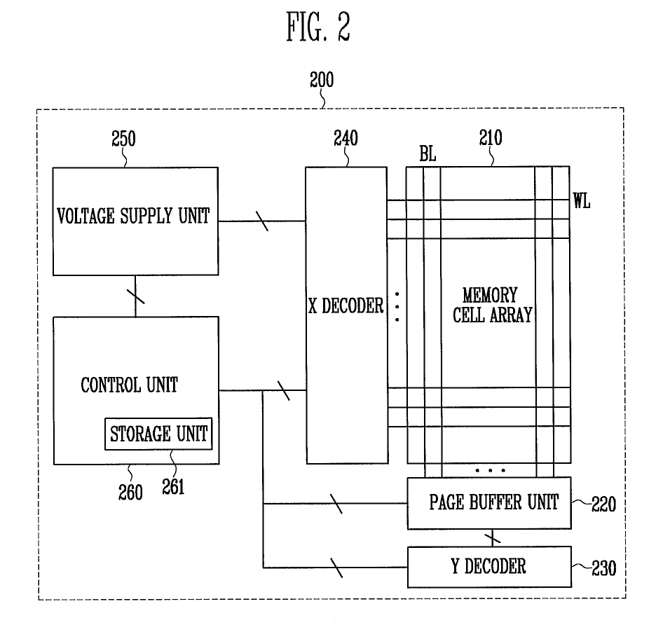

FIG. 2 is a block diagram of a nonvolatile memory device according to an embodiment.

Referring to FIG. 2, the nonvolatile memory device 200 includes a memory cell array 210, a page buffer unit 220, a Y decoder 230, an X decoder 240, a voltage supply unit 250, and a control unit 260.

The memory cell array 210 includes a plurality of memory blocks each having memory cells for storing data. The memory cells included in each memory block are coupled by a bit line and word lines and then selected. Furthermore, the memory cells include flag cells for storing a program state or information about an E/W cycle. The flag cell is provided in each word line and is configured to store the E/W cycle information on a word-line by word-line basis.

The page buffer unit 220 includes page buffer circuits coupled to the bit lines of the memory cell array 210. The page buffer circuit is configured to latch data to be programmed and transmit the data to a selected bit line, or read data stored in a memory cell coupled to a selected bit line and store the read data.

The Y decoder 230 is configured to provide a data input/output path to the page buffer circuits of the page buffer unit 220. The X decoder 240 is configured to enable the memory blocks of the memory cell array 210 and to couple the word line of an enabled memory block to a global word line for providing operating voltages.

The voltage supply unit 250 is configured to generate the operating voltages provided by the global word line, and the control unit 260 is configured to control the page buffer unit 220, the Y decoder 230, the X decoder 240, and the voltage supply unit 250.

Furthermore, the control unit 260 is configured to control the amount of an I-trip which is current flowing through, for example, a word line to a memory cell with the repetition of the E/W cycle. Thus, an operation control option, such as a program or read operation according to the I-trip, is changed. The control unit 260 includes a storage unit 261. The storage unit 261 may be configured to store E/W cycle information about each word line.

The E/W cycle refers to a cycle in which program and erase operations are performed on a memory cell. In general, the number of electrons trapped in a memory cell increases with an increase of the number of the E/W cycles that have been performed. Consequently, the threshold voltage of the memory cell rises, and the level of an I-trip is lowered.

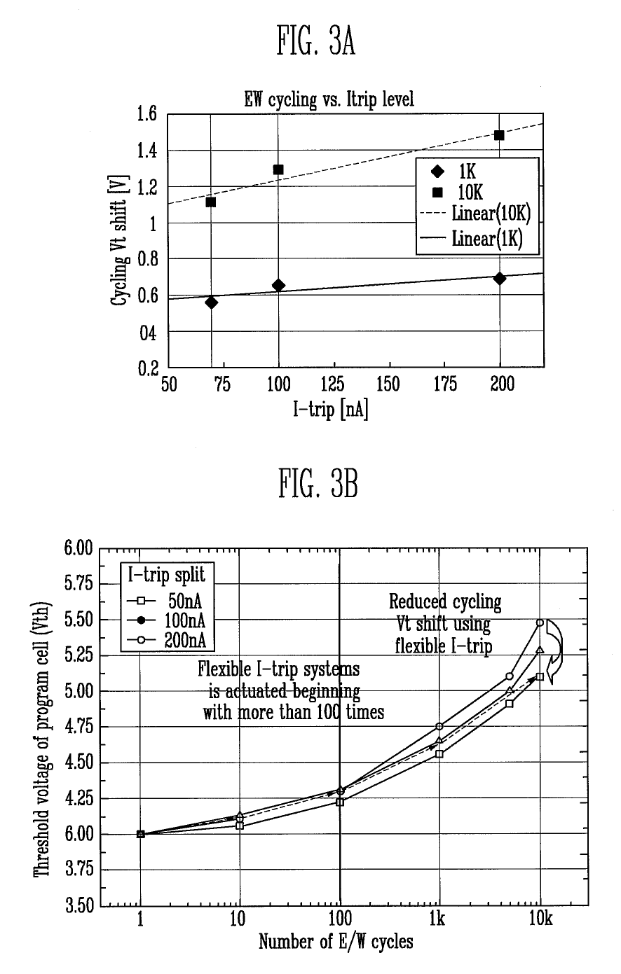

FIG. 3A is a diagram showing an I-trip which is changed according to the E/W cycle, FIG. 3B is a diagram showing a change in the program threshold voltage according to the E/W cycle, and FIG. 3C is a diagram showing the level of a change in the threshold voltage according to the E/W cycle and the I-trip.

From FIG. 3A, it can be seen that, with the repetition of the E/W cycle, the level of a change in the threshold voltage of a memory cell increases with an increase of the I-trip level. That is, when the I-trip level is small, the level of a change in the threshold voltage of the memory cell is small although the E/W cycle is repeated.

The following table shows, in terms of numerical values, I-trip levels and levels of a change in the threshold voltage of the memory cell with the repetition of the E/W cycle.

TABLE 1

| | |
|---|---|
| I-TRIP | E/W CYCLE |

| LEVEL | 100 | 1K | 5K | 10K |
|---|---|---|---|---|
| 70 nA | 0.23 | 0.56 | 0.91 | 1.11 |
| 100 nA | 0.31 | 0.66 | 1.1 | 1.29 |
| 200 nA | 0.27 | 0.69 | 10.3 | 1.48 |

Meanwhile, referring to FIG. 3B, when the number of E/W cycles that have been performed increases, voltage for reading a program cell is changed. Here, the level of a change in the threshold voltage of the program cell is small with a decrease in the I-trip level. Accordingly, if the I-trip level is changed slightly with an increase of the E/W cycles that have been performed, the threshold voltage of the memory cell is recognized as being small.

From FIG. 3B, it can be seen that the threshold voltage changes irrespective of the I-trip level when the accumulated number of the E/W cycles that have been performed becomes 100. In this case, when the I-trip level is low, the threshold voltage changes greatly.

However, it can be seen that, if the accumulated number of the E/W cycles that have been performed increases up to 10,000 (10K), a change in the threshold voltage is lowered with a decrease in the I-trip level.

FIG. 3C shows the levels of current flowing when a memory cell is turned on, and threshold voltages when the memory cell initially operates, when the E/W cycle for the memory cell is performed 1K times, and when the E/W cycle for the memory cell is performed 10K times. Here, when comparing the levels of a change in the threshold voltage in the case where the I-trip level is set low, that is the case indicated by the arrows “a,” in the case where the I-trip level is set high, that is the case indicated by the arrows “b,” and in the case where the I-trip level is set to change, that is the case indicated by the arrows “c,” it can be seen that a change in the threshold voltage is small in the case where the I-trip level is set to change, that is the case indicated by the arrows “c.”

An operation method for changing the I-trip level with the repetition of the E/W cycle is described below.

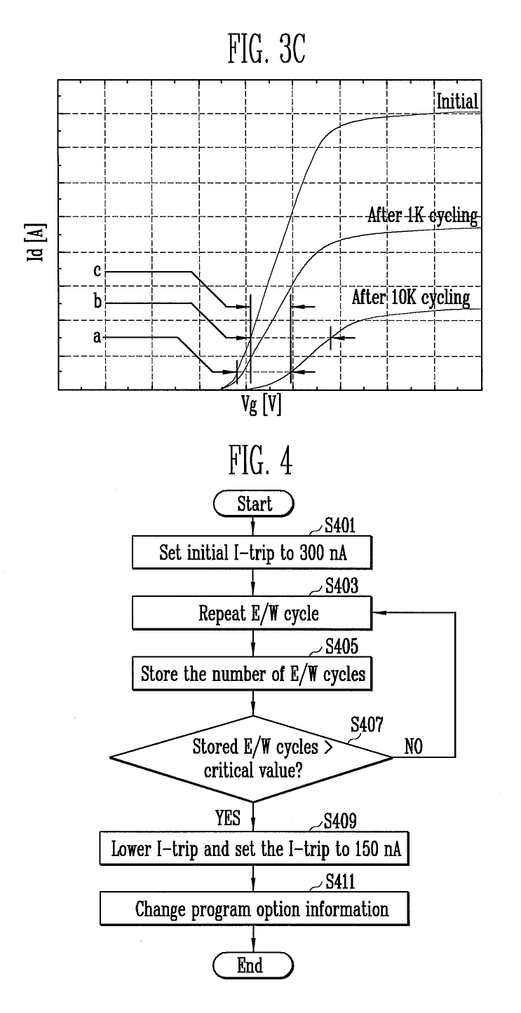

FIG. 4 is a flowchart illustrating the operation of the nonvolatile memory device according to an embodiment.

Referring to FIG. 4, when the nonvolatile memory device 200 initially operates, the I-trip level is set to 300 nA at step S401. This may change according to the specification of the nonvolatile memory device 200.

Several options when a program operation is performed according to the I-trip level are changed. That is, the number of times that a program pulse is applied, the level of a program verification voltage, etc. may change according to the I-trip level.

In the state in which the I-trip level is initially set to 300 nA, the nonvolatile memory device 200 repeatedly performs an E/W cycle for programming and erasing data at step S403.

Here, the number of E/W cycles that have been performed can be checked on a word-line by word-line basis. That is, the erase operation may be performed in the state in which not all of the word lines of the memory block are programmed, where some of the word lines may never be programmed depending on conditions.

Accordingly, in some cases, the E/W cycle for a certain word line might have been performed 100 times, and the E/W cycle for another word line might have been performed only about 50 times. This is because the E/W cycle indicates information about the number of times in which only the execution of an erase operation is counted after an actual program operation.

Information about the number of E/W cycles may be stored in the flag cell provided on a word-line by word-line basis or may be separately stored in the storage unit 261 of the control unit 260. Alternatively, the number of E/W cycles may not be stored on a word-line by word-line by word-line basis, but the number of E/W cycles for the entire memory block may be stored and the I-trip level may be controlled according to the stored number of E/W cycles.

When the nonvolatile memory device 200 according to the embodiment repeats the E/W cycle at step S403, information about the number of E/W cycles is stored on a word-line by word-line basis at step S405. It is then determined whether the stored E/W cycle information exceeds a set critical value at step S407.

The critical value indicates the number of unit cycles for controlling the I-trip level according to the number of E/W cycles, and it may be set to, for example, units of 1K, units of 2K, or units of 3K according to settings.

That is, when an operation initially begins, it is checked whether the number of stored E/W cycles exceeds 1K. If, as a result of the check, the number of E/W cycles exceeds 1K, it is checked whether the number of E/W cycles exceeds 2K, and so on.

If, as a result of the determination at step S407, the number of E/W cycles is determined to exceed the critical value, the I-trip level is lowered and then set to 150 nA again at step S409. A degree that the I-trip level is lowered may change according to the unit of a critical value. FIG. 4 according to the embodiment shows only a method of lowering the I-trip level from 300 nA to 150 nA only once. However, it is to be noted that the I-trip level may be subdivided into smaller levels according to the unit of a critical value of the E/W cycle and may be variably set in several decreasing steps.

After the I-trip level changes to 150 nA at step S409, the control unit 260 changes and sets option information for performing a corresponding program operation at step S411.

For example, since the I-trip level has changed, a verification voltage level for program verification can be changed. Thus, when the I-trip level changes to a small value, the verification voltage level is controlled to be low. This can include performing a method of previously storing a value which is set according to the I-trip level in the storage unit 261 and changing the I-trip level with the repetition of the E/W cycle so that a program option is automatically changed.

Furthermore, the reason why the I-trip level is changed according to the number of E/W cycles is that, if the I-trip level is lowered from the beginning, more program steps may have to be performed when an ISPP program operation is performed. Accordingly, the I-trip level is controlled according to a set number of E/W cycles so that the program time taken to perform the ISPP program operation does not increase.

As described above, in accordance with the method of operating a nonvolatile memory device according to this disclosure, the I-trip is changed according to the number of E/W cycles that have been executed. Accordingly, the cell margin can be secured and reliability of a memory cell can be improved.

What is claimed is:

1. A method of operating a nonvolatile memory device, comprising:
setting an initial cell current level;
performing program and erase operations for each word line of a memory block;
storing the cycling number of the program and erase operations;
comparing the cycling number with a critical cycling number of the program and erase operations;
lowering the initial cell current level when the cycling number are larger than the critical cycling number; and
changing a program operation option based on the lowered initial cell current level.

2. The method of claim 1, wherein the cycling number is stored in a flag cell coupled to each word line.

3. The method of claim 1, wherein the cycling number is stored in separate storage means.

4. The method of claim 1, wherein the cycling number is stored in a storage unit in a control unit for controlling the program operation.

5. The method of claim 1, wherein the program operation option comprises a program verification voltage level or a number of a pulse in a program operation.

6. The method of claim 5, wherein the program verification voltage level is lowered when lowering the initial cell current level.

7. A method of operating a nonvolatile memory device, comprising:
setting the initial cell current level;
performing program and erase operations for each memory block;
storing the cycling number of the program and erase operations;
comparing the cycling number with a critical cycling number of the program and erase operations;
lowering the initial cell current level when the cycling number are larger than the critical cycling number; and
changing a program operation option based on the lowered initial cell current level.

8. The method of claim 7, wherein the cycling number is stored in a flag cell coupled to each word line.

9. The method of claim 7, wherein the cycling number is stored in separate storage means.

10. The method of claim 7, wherein the cycling number is stored in a storage unit in a control unit for controlling the program operation.

11. The method of claim 7, wherein the program operation option comprises a program verification voltage level or a number of a pulse in a program operation.

12. The method of claim 11, wherein the program verification voltage level is lowered when lowering the initial cell current level.
